(19) United States
(12) Patent Application Publication
(10) Pub. No.: US 2024/0367357 A1
(43) Pub. Date: Nov. 7, 2024

(54) INJECTION MOLDING METHOD FOR MANUFACTURING PACKAGING STRUCTURE, PACKAGING STRUCTURE, AND CAMERA MODULE

(71) Applicant: Rayprus Technology (Foshan) Co., Ltd., Foshan (CN)

(72) Inventor: HSIN-YEN HSU, New Taipei (TW)

(21) Appl. No.: 18/408,781

(22) Filed: Jan. 10, 2024

(30) Foreign Application Priority Data
May 4, 2023 (CN) 202310496607.2

(51) Int. Cl. B29C 45/00; B29C 45/14; B29C 45/16; B29C 45/26; C03B 11/08

(52) U.S. Cl. CPC B29C 45/0062; B29C 45/0055; B29C 45/14639; B29C 45/1657; B29C 45/26; C03B 11/08; B29C 2045/0058; B29C 2045/1664; B29C 2045/2683

(57) ABSTRACT

An injection molding method which can isolate injection materials from flowing into the sensing area includes: providing an injection mold comprising a first mold and a second mold; placing a component to be packaged on the second mold; arranging a sealant on a non-sensing area of the component to be packaged; placing the first mold on the component to be packaged; injecting a molding material and curing the molding material to form an encapsulation portion; removing the injection mold. A packaging structure and a camera module carrying it are also disclosed.

### FIELD

The subject matter herein generally relates to packaging technology, and more particularly, to an injection molding method for manufacturing a packaging structure, the packaging structure, and a camera module.

### BACKGROUND

Existing photoelectric components (such as camera modules) generally use an injection molding method to encapsulate a chip on a substrate. The chip is electrically connected to the substrate by a wire, and the method can protect the connection area among the chip, the wire, and the substrate by plastic. The method is carried out by electrically connecting the chip on the substrate by the wire to form an intermedia product, placing the intermedia product on a lower mold, covering an upper mold on the chip, and injecting a plastic material onto the connection area among the chip, the wire, and the substrate. To isolate a sensing area of the chip from the plastic material, the upper mold needs to be equipped with a soft release film, which will cover the sensing area of the chip when the upper mold is placed on the lower mold. The release film is removed after the plastic material is solidified.

However, in order to ensure the adhesion between the release film and the upper mold, the thickness of the release film may not be too large. Such release film may have a small deformation ability, making it insufficient to seal the sensing area if the chip is inclined relative to the substrate.

Therefore, there is room for improvement in the art.

### BRIEF DESCRIPTION OF THE DRAWINGS

Implementations of the present disclosure will now be described, by way of embodiments only, with reference to the attached figures.

FIG. 1 is a flowchart of an injection molding method according to an embodiment of the present disclosure.

FIG. 2 is a cross-sectional view of an injection mold according to an embodiment of the present disclosure.

FIG. 3 is a cross-sectional view of an injection mold according to another embodiment of the present disclosure.

FIG. 4 to FIG. 8 are cross-sectional views showing the injection molding method using the injection mold of FIG. 2.

FIG. 9 is a cross-sectional view of a packaging structure according to an embodiment of the present disclosure.

FIG. 10 is a cross-sectional view of a camera module according to an embodiment of the present disclosure.

### DETAILED DESCRIPTION

Unless otherwise defined, all technical and scientific terms used herein have the same meaning as commonly understood by persons skill in the art. The terms used herein are only for the purpose of describing specific embodiments, and not intended to limit the embodiments of the present application.

It should be noted that all directional indications (such as up, down, left, right, front, back, etc.) in the embodiments of the present application are only used to explain the relative positional relationship or movement between various components under a certain posture (as shown in the drawings). If the specific posture changes, the directional indication also changes accordingly.

In the description of the present application, “plurality” means more than one unless expressly and specifically defined otherwise. It should be noted that when a component is referred to as being “fixed on” or “mounted on” another component, it may be directly on the other component or there may also be an intervening component. When a component is considered to be “set on” another component, it may be in direct contact with the other component or there may also be an intervening component. As used herein, the term “and/or” includes all and any combinations of one or more of related listed items.

Some embodiments of the present application will be described in detail below with reference to the drawings. The following embodiments and features of the embodiments may be combined with each other in the absence of conflict.

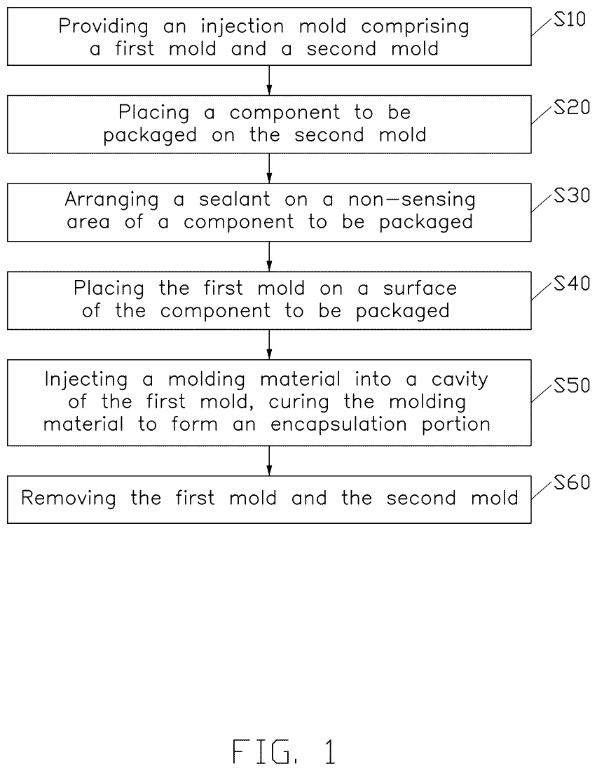

FIG. 1 illustrates a flowchart of a manufacturing method of a packaging structure in accordance with an embodiment. The method is provided by way of embodiments, as there are a variety of ways to carry out the method. Each block shown in FIG. 1 represents one or more processes, methods, or subroutines carried out in the method. Furthermore, the illustrated order of blocks can be changed. Additional blocks may be added or fewer blocks may be utilized, without departing from this disclosure. The method can begin at S10.

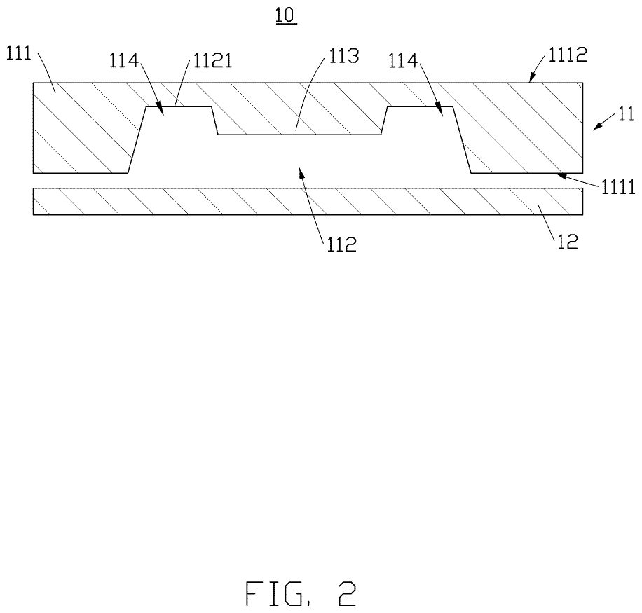

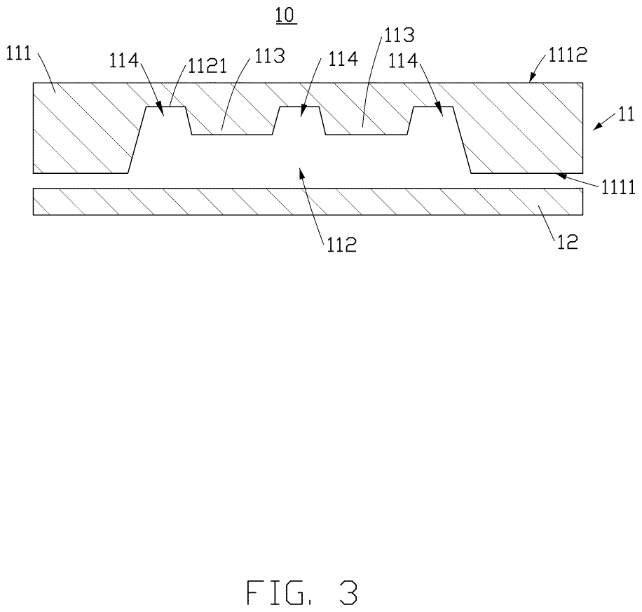

Step S10, referring to FIGS. 2 and 3, an injection mold 10 is provided.

The injection mold 10 includes a first mold 11 and a second mold 12 opposite to each other. The first mold 11 includes a body portion 111, and the body portion 111 defines a groove 112. The groove 112 is provided with at least one protrusion 113 that divides the groove 112 into a plurality of cavities 114.

In some embodiments, the first mold 11 is referred to as the upper mold, and the second mold 12 is referred to as the lower mold. As shown in FIGS. 2 and 3, the body portion 111 is generally cubic in structure, and has a first surface 1111 and a second surface 1112 opposite to the first surface 1111. The first surface 1111 is partially recessed toward the second surface 1112 to form the groove 112, and a bottom wall 1121 of the groove 112 partially extends toward the first surface 1111 to form the protrusion 113. The height of the protrusion 113 is less than the depth of the groove 112, so that the surface of the protrusion 113 facing away from the second surface 1112 is lower than the first surface 1111. The protrusion 113 may also be a structure formed by removing a portion of the body portion 111 between adjacent two grooves 112. The material of the protrusion 113 may be the same as or different from the material of the body portion 111. The protrusion 13 may be made of an elastic material.

In FIG. 2, there is one protrusion 13 in the groove 112, and there are two cavities 114. In FIG. 3, there are two protrusions 3 in the groove 112, and there are three cavities 114. In other embodiments, the number of protrusions 113 may be greater than two, and the number of cavities may be greater than three.

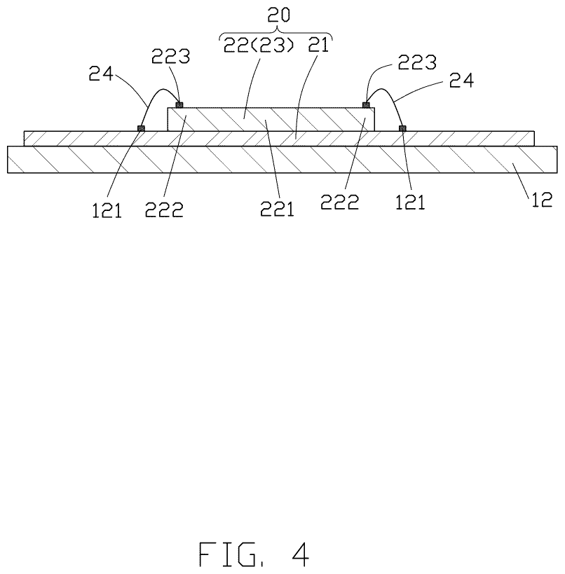

Step S20, referring FIG. 4, a component to be packaged 20 (hereinafter, “component 20”) is placed on the second mold 22.

The component 20 includes a substrate 21 and an optoelectronic element 22 fixed on the surface of the substrate. The substrate 21 is located between the second mold 12 and the optoelectronic element 22. The substrate 21 may be a printed circuit board, and the printed circuit board may be single-layer or multi-layer, which is not limited in this application.

The optoelectronic element 22 includes a sensing area 221 and a non-sensing area 222 surrounding the sensing area 221. The sensing area 221 is generally located at the central region of the optoelectronic element 22, and the non-sensing area 222 is generally located at the edge region of the optoelectronic element 22. In this embodiment, the optoelectronic element 22 is a photosensitive chip 23. The sensing area 221 is the photosensitive area of the photosensitive chip 23, which includes a plurality of micro-lenses on a micro scale. The non-sensing area 222 is the non-photosensitive area of the photosensitive chip 23. The photosensitive chip 23 may be but is not limited to a complementary metal oxide semiconductor (CMOS). In other embodiments, the optoelectronic element 22 may also be a laser diode 27. Multiple photosensitive chips 23 and/or multiple laser diodes 27 may be encapsulated simultaneously on the substrate 21.

In some embodiments, when the optoelectronic element 22 is the photosensitive chip 23, the component 20 may be manufactured by attaching the photosensitive chip 23 onto the substrate 21, and electrically connecting the photosensitive chip 23 to the substrate 21 by a wire 24.

Furthermore, in some embodiments, the back surface (the surface away from the photosensitive area) of the photosensitive chip 23 may be adhered to the substrate 21 by adhesive (not shown in the FIG. 4).

As shown in FIG. 4, in some embodiments, the non-sensing area 222 of the optoelectronic element 22 (photosensitive chip 23) has a first pad 223, the substrate 21 has a second pad 121. The number of each of the first pad(s) 223 and second pad(s) 121 may be multiple, which is not limited herein. The first pads 223 on the optoelectronic element 22 (photosensitive chip 23) may be connected to the second pads 121 on the substrate 21 by wire bonding, thereby electrically connecting the optoelectronic element 22 (photosensitive chip 23) to the substrate 21.

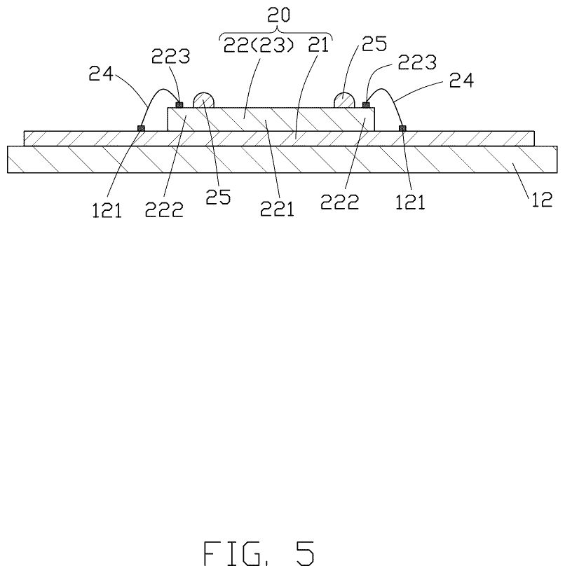

Step S30, referring to FIG. 5, a sealant 25 is applied to the non-sensing area 222 of the photoelectric element 22, and the sealant 25 is arranged around the sensing area 221.

In some embodiments, the sealant 25 may be applied to the outer side of the sensing area 221 by dispensing or spraying. The sealant 25 may be or may not be an adhesive. If the sealant 25 is adhesive, the sealant 25 can adhere dust and other impurities thereon, thereby reducing their impact on the optoelectronic element 22.

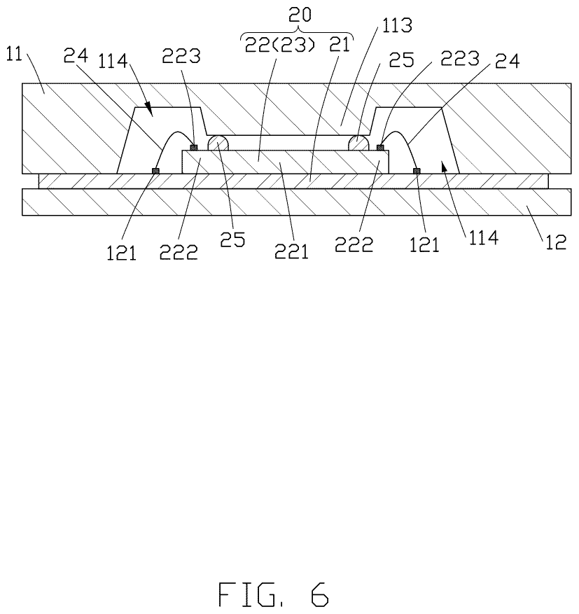

Step S40, referring to FIG. 6, the first mold 11 is placed on the surface of the component 20, so that the protrusion 113 of the first mold 11 is abutted against the sealant 25 and the cavity 114 covers the non-sensing area 222 of the optoelectronic element 22. The cavity 114 also covers a portion of the surface of the substrate 21. The protrusion 113 may be made of an elastic material, so that the protrusion 113 can be abutted against the sealant 25 more closely, preventing the injection material from entering the sensing area 221 during encapsulation. In the present application, the protrusion 113 being abutted against the sealant 25 means that the protrusion 113 is in contact with the sealant 25 and there is a force between them.

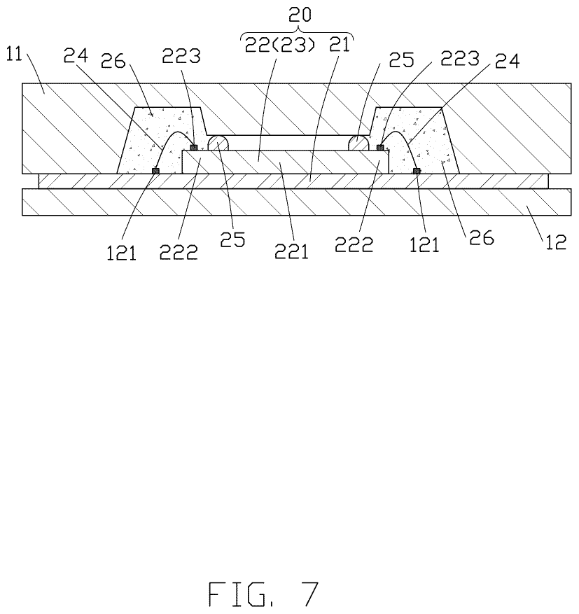

Step S50, referring to FIG. 7, an injection material is injected into the cavity 114 and then the injection material is cured, thereby forming an encapsulation portion 26 on the surface of the non-sensing area 222 and a portion of the surface of the substrate 21.

In some embodiments, the injection material is epoxy resin. The injection material may be cured by heating or UV illumination.

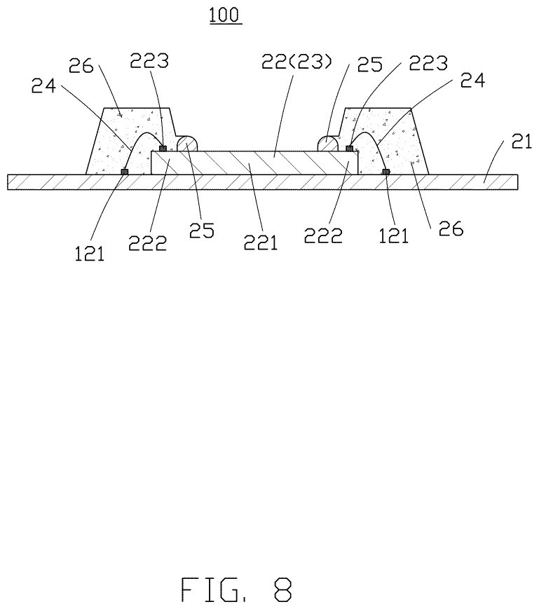

Step S60, referring to FIG. 8, the first mold 11 and the second mold 12 are removed to complete the encapsulation.

Referring to FIGS. 8, an embodiment of the present application provides a packaging structure 100 that is encapsulated by the above-mentioned injection molding method.

As shown in FIG. 8, the packaging structure 100 includes a substrate 21, an optoelectronic element 22, and an encapsulation portion 26. The optoelectronic element 22 is fixed on the surface of the substrate 21 and electrically connected to the substrate 21. The optoelectronic element 22 includes a sensing area 221 and a non-sensing area 222 surrounding the sensing area 221. The non-sensing area 222 is provided with a sealant 25, which is arranged around the sensing area 221. In other words, the sealant 25 serves as a boundary between the sensing area 221 and the non-sensing area 222. The inner side of the sealant 25 defines the sensing area 221, while its outer side defines the non-sensing area 222. The encapsulation portion 26 covers the non-sensing area 222 and a portion of the surface of the substrate 21. The encapsulation portion 26 is disposed adjacent to the sealant 25, and may be in contact or not in contact with the sealant 25.

As shown in FIG. 8, in this embodiment, the optoelectronic element 22 is a photosensitive chip 23. The substrate 21 may be a printed circuit board, and the printed circuit board may be single-layer or multi-layer, which is not limited herein.

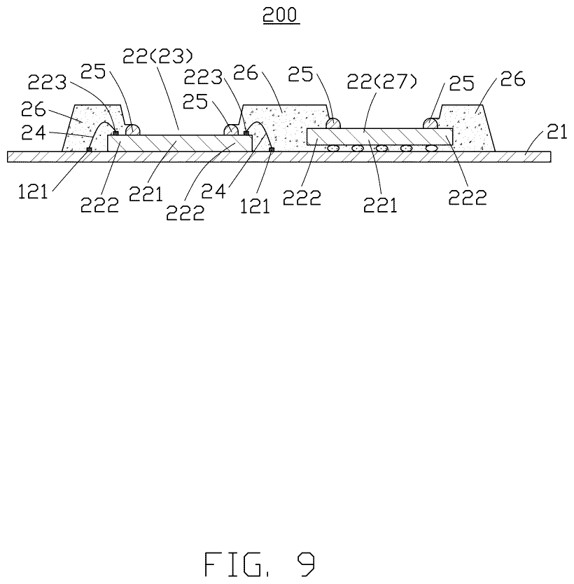

As shown in FIG. 9, another embodiment of the present application provides a packaging structure 200. The packaging structure 200 also includes a substrate 21, an optoelectronic element 22, and an encapsulation portion 26. The difference between the packaging structure 200 shown in FIG. 9 and the packaging structure 100 shown in FIG. 8 is that the optoelectronic element 22 of the packaging structure 200 includes a photosensitive chip 23 and a laser diode 27. The remaining settings of the packaging structure 200 are roughly the same as those of the packaging structure 100, and will not be described here. In other embodiments, the optoelectronic element 22 nay also be other electronic components.

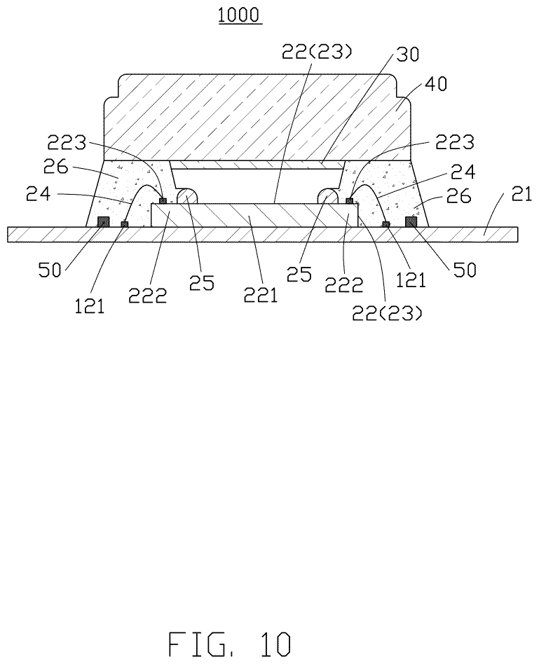

Referring to FIG. 10, the present application also provides a camera module 1000 including the above-mentioned packaging structure 100. In the packaging structure 100, the optoelectronic element 22 is a photosensitive chip 23. In at least one embodiment, the photosensitive chip 23 may be a CMOS.

As shown in FIG. 10, the camera module 1000 may also include a filter 30. The filter 30 is provided on the encapsulation portion 26, and is arranged opposite to the photosensitive chip 23. In at least one embodiment, the filter 30 is arranged opposite to the sensing area 221 of the photosensitive chip 23. In some embodiments, the filter 30 is directly fixed on the encapsulation portion 26. After the injection material is injected, the filter 30 is placed at a position on the injection material and corresponds to the sensing area 221 of the photosensitive chip 23. After curing the injection material, the filter 30 is fixed on the encapsulation portion 26 formed by curing the injection molding material. In other embodiments, the filter 30 may be fixed on the encapsulation portion 26 through an adhesive layer. The filter 30 may be a blue glass filter allowing permitted light only to pass through, thereby ensuring imaging quality.

As shown in FIG. 10, the camera module 1000 may also include a lens 40. The lens 40 is disposed on a surface of the encapsulation portion 26 away from the substrate 21. The filter 30 is disposed between the lens 40 and the photosensitive chip 23, and is located on an optical path of the lens 40.

As shown in FIG. 10, the camera module 1000 may also include a passive component 50. The number of the passive component 50 may be one or more, and there is no limitation in this application. The passive component 50 is disposed on the surface of the substrate 21 and is encapsulated by the encapsulation portion 26, thus the passive component 50 is difficult to fall off. The passive component 50 may be electrically connected to the substrate 21. The passive components may be, but not limited to, a resistor, a capacitor, an inductor and so on.

The present application sets the sealant 25 around the sensing area 221 of the optoelectronic element 22, and sets the protrusion 113 in the injection mold 10, so that the protrusion 113 can be abutted against the sealant 25 during injection molding. Thus, the sealant 25 can seal and protect the sensing area 221, thereby reducing the probability of injection materials entering the sensing area 221. Moreover, the height of the sealant 25 can compensate for the height difference between the component 20 and the injection mold 10 (the protrusion 113) when they are in contact with each other. In the present application, the existing release film is not needed, so that it has no need to change internal shape of the molds to adapt to the release film with insufficient deformation ability.

The above descriptions are some specific embodiments of the present application, but the actual application process cannot be limited only to these embodiments. For those of ordinary skill in the art, other modifications and changes made according to the technical concept of the present application should all belong to the protection scope of the present application.

What is claimed is:

1. An injection molding method for manufacturing a packaging structure, comprising:
providing an injection mold, wherein the injection mold comprises a first mold and a second mold, the first mold comprises a body portion, the body portion defines a groove, the groove is provided with at least one protrusion, and the at least one protrusion divides the groove into a plurality of cavities;
placing a component to be packaged on the second mold, wherein the component to be packaged comprises a substrate and an optoelectronic element fixed on the substrate, and the optoelectronic element comprises a sensing area and a non-sensing area surrounding the sensing area;
applying a sealant on the non-sensing area, and the sealant surrounding the sensing area;
placing the first mold on the component to be packaged, causing the protrusion to abut against the sealant and the plurality of cavities to cover the non-sensing area;
injecting an injection material into the plurality of cavities, curing the injection material to form an encapsulation portion on the non-sensing area and the substrate; and
removing the first mold and the second mold to obtain the packaging structure.

2. The injection molding method of claim 1, wherein the optoelectronic element comprises a photosensitive chip and/or a laser diode.

3. The injection molding method of claim 1, wherein the optoelectronic element is a photosensitive chip, the injection molding method further comprises a preparation method of the component to be packaged comprising:
attaching the photosensitive chip to the substrate;
electrically connecting the photosensitive chip to the substrate by a wire.

4. The injection molding method of claim 3, wherein the non-sensing area comprises a first pad, the substrate comprises a second pad, and the wire connects the first pad with the second pad, thereby electrically connecting the photosensitive chip and the substrate.

5. The injection molding method of claim 3, wherein the wire is a gold wire.

6. The injection molding method of claim 3, wherein the wire is a silver wire.

7. The injection molding method of claim 1, wherein the injection material comprises epoxy resin.

8. The injection molding method of claim 1, wherein the body portion of the first mold has a first surface and a second surface opposite to the first surface, the first surface is partially recessed toward the second surface to form the groove, the at least one protrusion is formed on a bottom wall of the groove, and a surface of each of the at least one protrusion facing away from the second surface is lower than the first surface.

9. A packaging structure comprising:
a substrate;
an optoelectronic element arranged on and electrically connected to the substrate, the optoelectronic element comprising a sensing area and a non-sensing area surrounding the sensing area;
a sealant formed on the non-sensing area and surrounding the sensing area; and
an encapsulation portion covering the non-sensing area and the substrate and connecting to the sealant.

10. The packaging structure of claim 9, wherein the optoelectronic element further comprises a photosensitive chip and/or a laser diode.

11. The packaging structure of claim 9, wherein the non-sensing area comprises a first pad, the substrate comprises a second pad, and the first pad and the second pad are electrically connected by a wire.

12. The packaging structure of claim 11, wherein the wire is a gold wire or a silver wire.

13. The packaging structure of claim 9, wherein the encapsulation portion comprises epoxy resin.

14. A camera module comprising:
a packaging structure, the packaging structure comprising:
a substrate;
a photosensitive chip arranged on and electrically connected to the substrate, the photosensitive chip comprising a sensing area and a non-sensing area surrounding the sensing area;
a sealant formed on the non-sensing area and surrounding the sensing area; and
an encapsulation portion covering the non-sensing area and the substrate and connecting to the sealant.

15. The camera module of claim 14, wherein the non-sensing area comprises a first pad, the substrate comprises a second pad, and the first pad and the second pad are electrically connected by a wire.

16. The camera module of claim 15, wherein the wire is a gold wire or a silver wire.

17. The camera module of claim 14 further comprising a filter, wherein the filter is arranged on the encapsulation portion, and the filter is arranged opposite to the photosensitive chip.

18. The camera module of claim 17, wherein the filter is opposite to the sensing area.

19. The camera module of claim 17, further comprising a lens, wherein the lens is arranged on a surface of the encapsulation portion facing away from the substrate, and the filter is located on an optical path of the lens.

20. The camera module of claim 14 further comprising a passive element, wherein the passive element is arranged on a surface of the substrate and covered by the encapsulation portion.
